(19) United States
(12) Patent Application Publication
(10) Pub. No.: US 2021/0328066 A1
(43) Pub. Date: Oct. 21, 2021

(54) THIN FILM TRANSISTOR, DISPLAY SUBSTRATE, DISPLAY PANEL, AND METHOD OF FABRICATING A THIN FILM TRANSISTOR

(71) Applicants: Chongqing BOE Optoelectronics Technology Co., Ltd., Chongqing (CN); BOE TECHNOLOGY GROUP CO., LTD., Beijing (CN)

(72) Inventors: Jun Wang, Beijing (CN); Zhonghao Huang, Beijing (CN); Yongliang Zhao, Beijing (CN); Seungmoo Rim, Beijing (CN)

(73) Assignees: Chongqing BOE Optoelectronics Technology Co., Ltd., Chongqing (CN); BOE Technology Group Co., Ltd., Beijing (CN)

(21) Appl. No.: 16/330,860

(22) PCT Filed: May 3, 2018
(86) PCT No.: PCT/CN2018/085433

§ 371 Date: Mar. 6, 2019

(30) Foreign Application Priority Data
Jan. 2, 2018 (CN) 201810002293.5

(51) Int. Cl. H01L 29/786; H01L 29/66

(52) U.S. Cl. CPC H01L 29/78618; H01L 29/78696; H01L 29/78609; H01L 29/6675; H01L 29/78663

(57) ABSTRACT

The present application provides a thin film transistor having an active layer. The active layer includes a source electrode contact part, a drain electrode contact part, and a channel part between the source electrode contact part and the drain electrode contact part. The channel part includes at least a first portion and a second portion different from the first portion. The second portion has an enhanced ability to capture off-state leaking carriers as compared to the first portion.

### CROSS-REFERENCE TO RELATED APPLICATION

This application claims priority to Chinese Patent Application No. 201810002293.5, filed Jan. 12, 2018, the contents of which are incorporated by reference in the entirety.

### TECHNICAL FIELD

The present invention relates to display technology, more particularly, to a thin film transistor, a display substrate, a display panel, and a method of fabricating a thin film transistor.

### BACKGROUND

Display devices such as liquid crystal display (LCD) and organic light-emitting diode (OLED) have been widely used LCD and OLED display devices use thin film transistor (TFT) to control pixels in the display panel. Examples of TFT include amorphous silicon TFT, polycrystalline silicon TFT, single crystal silicon TFT, and metal oxide TFT. A thin film transistor may be classified into a top gate type or a bottom Rate type.

### SUMMARY

In one aspect, the present invention provides thin film transistor, comprising an active layer; Wherein the active layer comprises a source electrode contact part, a drain electrode contact part, and a channel part between the source electrode contact part and the drain electrode contact part; wherein the channel part comprises at least a first portion and a second portion different from the first portion, the second portion having an enhanced ability to capture off-state leaking carriers as compared to the first portion.

Optionally, off-state energy band levels of a material of the second portion are lower than off-state energy band levels of a material of the first portion.

Optionally, off-state energy band levels of materials of the second portion, the source electrode contact part, and the drain electrode contact part are lower than the off-state energy band levels of the material of the first portion.

Optionally, the first portion comprises at least a first sub-part and a second sub-part spaced apart from each other by the second portion.

Optionally, the second portion comprises at least a third sub-part and a fourth sub-part spaced apart from each other by the first portion.

Optionally, the second portion comprises a same semiconductor host material doped with a same dopant of a doping concentration in a same range as at least one of the source electrode contact part and the drain electrode contact part.

Optionally, the source electrode contact part, the drain electrode contact part, the first portion of the channel part, and the second portion of the channel part comprises a same semiconductor host material.

Optionally, the source electrode contact part, the drain electrode contact part, the first portion of the channel part, and the second portion of the channel part constitute a single layer structure in a same layer.

Optionally, the active layer has a multi-layer structure comprising a first layer, a second layer on the first layer, a third layer on a side of the second layer distal to the first layer, and a fourth layer on a side of the third layer distal to the second layer; the second layer constitutes the second portion of the channel part; the first layer and the third layer constitute the first portion of the channel part; and the fourth layer constitutes the source electrode contact part and the drain electrode contact part.

Optionally, the first portion comprises at least a first sub-part, a second sub-part, and a fifth sub-part spaced apart from each other by the second portion, the first sub-part being in the first layer, the second sub-part and the fifth sub-part being in the third layer; the second portion comprises at least a third sub-part and a fourth sub-part spaced apart from each other by the first portion, the third sub-part and the fourth sub-part being in the second layer; the second sub-part is spaced apart from the first sub-part by the third sub-part; the fifth sub-part is spaced apart from the first sub-part by the fourth sub-part the third sub-part and the fourth sub-part are spaced apart from each other by the first sub-part; the source electrode contact part and the third sub-part are spaced apart from each other by the second sub-part; and the drain electrode contact part and the fourth sub-part are spaced apart from each other by the fifth sub-part.

Optionally, the second portion comprises a doped semiconductor material; and the first portion comprises an undoped semiconductor material or a semiconductor material less doped than the second portion.

Optionally, the first portion comprises an undoped amorphous silicon material; and each of the source electrode contact part, the drain electrode contact part and the second portion of the channel part comprises an N⁺heavily doped amorphous silicon material.

Optionally, the second portion has a doping concentration in a range of approximately 10¹⁷ atom/cm³ to approximately 10²¹ atom/cm³.

In another aspect, the present invention provides a display substrate comprising the thin film transistor described herein or fabricated by a method described herein.

In another aspect, the present invention provides display panel comprising the display substrate described herein.

In another aspect, the present invention provides a method of fabricating a thin film transistor, comprising forming an active layer; wherein forming the active layer comprises forming a source electrode contact part, forming a drain electrode contact part, and forming a channel part between the source electrode contact part and the drain electrode contact part; wherein forming the channel part comprises forming at least a first portion and forming a second portion different from the first portion, the second portion formed to capture off-state leaking carriers.

Optionally, forming the active layer comprises forming a semiconductor material layer on a base substrate; patterning the semiconductor material layer using, a half-tone mask plate or a gray-tone mask plate; and doping a first region of the semiconductor material layer thereby forming the source electrode contact part, the drain electrode contact part, and the second portion of the channel part.

Optionally, forming the active layer comprises forming a first semiconductor material layer on a base substrate; forming a second semiconductor material layer on a side of the first semiconductor material layer distal to the base substrate: forming a third semiconductor material layer on a side of the second semiconductor material layer distal to the first semiconductor material layer; forming a fourth semiconductor material layer on a side of the third semiconductor material layer distal to the second semiconductor material layer; patterning first semiconductor material layer, the second semiconductor material layer, the third semiconductor material layer, and the fourth semiconductor material layer, thereby forming an active layer having a first layer, a second layer on the first layer, a third layer on a side of the second layer distal to the first layer, and a fourth layer on a side of the third layer distal to the second layer; wherein a first sub-part of the first portion of the channel part in the first layer; a third sub-part and a fourth sub-part of the second portion of the channel part in the second layer; a second sub-part and a fifth sub-part of the first portion of the channel part in the third layer; and a source electrode contact part and a drain electrode contact part in the fourth layer.

Optionally, forming the second semiconductor material layer comprises depositing a semiconductor host material layer and doping the semiconductor host material layer; and forming the fourth semiconductor material layer comprises depositing a semiconductor host material layer and doping the semiconductor host material layer.

Optionally, the method further comprises forming a source electrode and a drain electrode; wherein patterning the first semiconductor material layer, the second semiconductor material layer, the third semiconductor material layer, and the fourth semiconductor material layer comprises removing a portion of the fourth semiconductor material layer, a portion of the third semiconductor material layer, a portion of the second semiconductor material layer using the source electrode and the drain electrode as a mask plate.

### BRIEF DESCRIPTION OF THE FIGURES

The following drawings are merely examples for illustrative purposes according to various disclosed embodiments and are not intended to limit the scope of the present invention.

FIG. 1 illustrates a thin film transistor in an ON state in some embodiments according to the present disclosure.

FIG. 2 illustrates a thin film transistor in an OFF state in some embodiments according to the present disclosure.

FIG. 3 illustrates energy levels of various portions of a thin film transistor in an OFF state in some embodiments according to the present disclosure.

FIG. 4 is a schematic diagram illustrating the, structure of a thin film transistor in some embodiments according to the present disclosure.

FIG. 5 is a schematic diagram illustrating energy band levels of various portions of a channel part of a thin film transistor in some embodiments according to the present disclosure.

FIG. 6 is a schematic diagram illustrating the structure of a thin film transistor in sonic embodiments according to the present disclosure.

FIG. 7 is a flow chart illustrating a method of fabricating a thin film transistor some embodiments according to the present disclosure.

FIG. 8 is a flow chart illustrating a method of fabricating a thin film transistor in some embodiments according to the present disclosure.

FIGS. 9A to 9C illustrate a process of fabricating a thin film transistor in some embodiments according to the present disclosure.

FIG. 10 is a flow chart illustrating a method of fabricating a thin film transistor in sonic embodiments according to the present disclosure.

FIGS. 11A to 11D illustrate a process of fabricating a thin film transistor in some embodiments according to the present disclosure.

FIG. 12 is a schematic diagram illustrating the structure of a display apparatus in some embodiments according to the present disclosure.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed.

Off-state leaking current in a thin film transistor greatly affects the performance of the thin film transistor. For example, a large off-state leaking current makes it difficult for the display panel to maintain image display, thus requires a higher frame frequency, which leads to a higher power consumption. Moreover, off-state leaking current is associated with. various display defects such as crosstalk, residual image, and flicker, severely affecting display quality,

Accordingly, the present disclosure provides, inter alfa a: thin film transistor, a display substrate, a display panel, and a method of fabricating a thin film transistor that substantially obviate one or more of the problems due to limitations and disadvantages of the related art. In one aspect, the present disclosure provides a thin film transistor haying an active layer. In some embodiments, the active layer includes a source electrode contact part, a drain electrode contact part, and a channel part between the source electrode contact part and the drain electrode contact part. Optionally, the channel part includes at least a first portion and a second portion different from the first portion, the second portion having an enhanced ability to capture off-state leaking carriers as compared to the first portion.

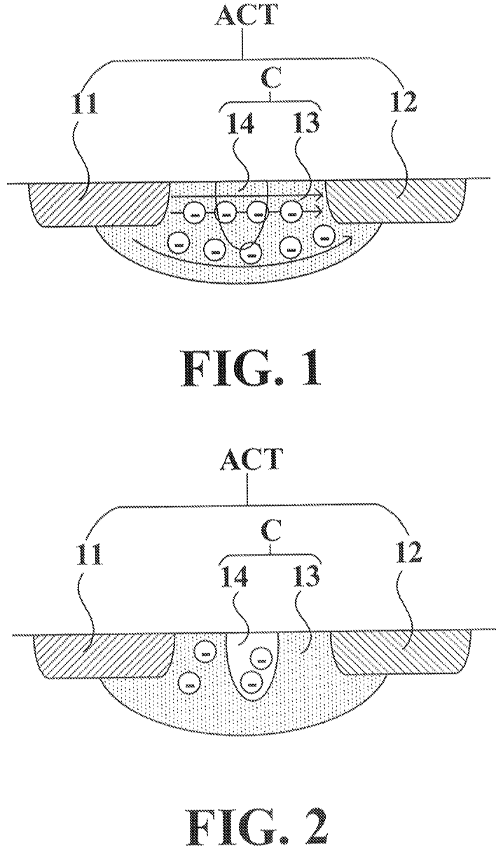

FIG. 1 illustrates a thin film transistor in an ON state in some embodiments according to the present disclosure. FIG. 2 illustrates a thin film transistor in an OFF state in sonic embodiments according to the present disclosure. Referring to FIG. 1 and FIG. 2, the thin film transistor includes an active layer ACT. The active layer ACT includes a source electrode contact part 11, a drain electrode contact part 12, and a channel part C between the source electrode contact part 11 and the drain electrode contact part 12. Optionally, the channel part C includes at least a first portion 13 and a second portion 14 different from the first portion 13. Optionally, the second portion 14 has an enhanced ability to capture off state leaking carriers as compared to the first portion 13. When the thin film transistor is in an ON state, the channel part C, including the first portion 13 and the second portion 14, forms a carrier channel between the source electrode contact part 11 and the drain electrode contact part 12. FIG. 1 shows charge carriers continue to migrate from the source electrode contact part 11 to the drain electrode contact part 12 through a carrier channel formed in the channel part C. When the thin film transistor is in an OFF state, the second portion 14 captures off-state leaking carriers between the source electrode contact part 11 and the drain electrode contact part 12. FIG. 2 shown leaking charge carriers being captured by the second portion 14, thereby suppressing leaking current between the source electrode contact part 11 and the drain electrode contact part 12 when the thin film transistor is in an OFF state. Optionally, the second portion 14 has an enhanced ability to capture off-state leaking carriers as compared to the first portion 13. Optionally, the second portion 14 is at least partially embedded in the first portion 13. By having the second portion 14 for capturing off-state leaking carriers, movements of off-state leaking carriers in the channel part C are restricted, thereby reducing or eliminating off-state leaking current in the thin film transistor.

In some embodiments, the source electrode contact part 11 and the drain electrode contact part 12 have a higher carrier mobility rate or a higher electrical conductivity or both as compared to the channel part C. Optionally, each of the source electrode contact part 11 and the drain electrode contact part 12 forms ohmic. contact with an electrode structure (e.g., a source electrode or a drain electrode), thereby facilitating transportation of charge carriers in and out of the active layer ACT. The channel part C has semiconductor characteristics corresponding to desired parameters, and is configured to control the source drain current between the source electrode contact part 11 and the drain electrode contact part 12 under the control of a gate voltage.

In some embodiments, the second portion 14 is configured to have an enhanced ability to capture charge carriers when the thin film transistor is in an OFF state as compared to when the thin film transistor is in an ON state. For example, the second portion 14 is configured to capture off-state leaking carriers when the thin film transistor is in an OFF state, but is configured to capture charge carriers to a much less degree, not to capture charge carriers at all when the thin film transistor is in an ON state. By having this design, the source drain current due to the movements of the charge carrier when the thin film transistor is in an ON state is not affected, or only minimally affected, by the present of the second portion 14. Optionally, the carrier capturing function of the second portion 14 only becomes observable when the thin film transistor is in an OFF state.

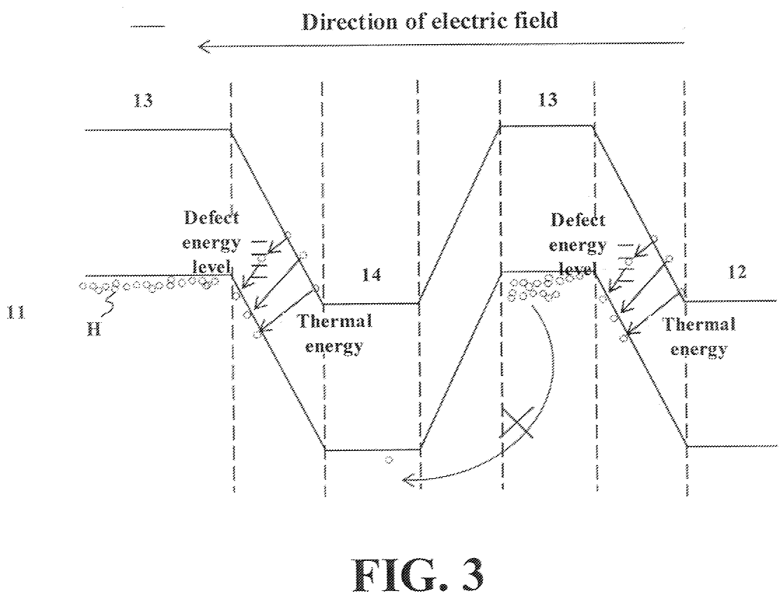

FIG. 3 illustrates energy levels of various portions of a thin film transistor in an OFF state in some embodiments according to the present disclosure. Referring to FIG. 3, a thin film transistor is in an OFF state. Due to the voltage at the source electrode and the drain electrode, an electric field in the active layer is foamed along a direction as shown in FIG. 3, i.e., along a direction from the drain electrode contact part 12 to the source electrode contact part 11. Under the electric field, energy band levels of the drain electrode contact part 12 and the second portion 14 of the channel part are relatively lower than an energy band level of the first portion 13. A leaking current flows from the source electrode contact part 11 to the drain electrode contact part 12. As shown in FIG. 3, the channel part includes a first portion 13 and a second portion 14. The first portion 13 includes at least a first sub-part (between the drain electrode contact part 12 and the second portion 14) and a second sub-part (between the source electrode contact part 11 and the second portion 14) spaced apart from each other by the second portion 14. Distribution of hole carriers H (empty circles in FIG. 3) in the channel part is depicted in FIG. 3. When the thin film, transistor is in an OFF state, a leaking current is formed due to movements of leaking carriers. For example, movements of electron carriers can be realized by at least three mechanisms: (1) trap-assisted tunneling; (2) thermally-assisted tunneling; and (3) electric field-assisted tunneling. Typically, the leaking current is formed by a combination of all three mechanisms. Moreover, the greater the electric field, the higher probability the tunneling occurs. Referring to FIG. 3, electron carriers can move from the first sub-part (between the drain electrode contact part 12 and the second portion 14) of the first portion 13 to the drain electrode contact part 12 by tunneling. However, the first sub-part and the second sub-part of the first portion 13 are spaced apart by the second portion 14, which presents a relatively high energy barrier to electron carriers to overcome. Moreover, the greater the electric field, the higher the energy barrier it presents. The presence of the energy barrier created by the second portion 14 makes it very difficult for electron carriers to move from the second sub-part of the first portion 13, across the second portion 14, to reach the first sub-part of the first portion 13. Thus, movements of electron carriers across the second portion 14 are highly restricted, thereby reducing or eliminating the leaking current.

Similarly, when the thin film transistor is in an OFF state, hole carriers entering into the channel part from the drain electrode contact part 12 must travel through the second portion 14 in order to move from the first sub-part of the first portion 13 to the second sub-part of the first portion 13. The second portion 14's ability to capture leaking carriers, which is positively correlated to the amplitude of the electric field, makes it very difficult for hole carriers to move from the first sub-part of the first portion 13, across the second portion 14, to reach the second sub-part of the first portion 13. The reduction in the mobility rate of hole carriers between the chain electrode contact part 12 and the source electrode contact part 11 results in a reduction or elimination of the leaking current.

In some embodiments, the channel part is in contact with the source electrode through the source electrode contact part 11, and in contact with the drain electrode through the drain electrode contact part 12. Optionally, multiple regions of the channel part are in contact with the source electrode, e.g., one of multiple regions is in contact with the source electrode through the source electrode contact part 11, and another of the multiple regions is in contact with the source electrode directly (e.g., without any intermediate structure or component). Similarly, in some embodiments, multiple regions of the channel part are in contact with the drain electrode, e, g, one of multiple regions is in contact with the drain electrode through the drain electrode contact part 12, and another of the multiple regions is in contact with the drain electrode directly (e.g., without any intermediate structure or component). In regions where a direct contact occurs, the contact resistance at the contact interface is relatively much higher as compared to the contact resistance where the source electrode contact part 11 or the drain electrode contact part 12 is present. An amount of leaking carriers moving across the direct contact interface is negligible as compared to the leaking carriers movement due to the tunneling effects. By having the second portion 14 for capturing off-state leaking carriers, off-state leaking current in the thin film transistor is reduced or eliminated.

In some embodiments, the first portion 13 includes at least a first sub-part and a second sub-part spaced apart from each other by the second portion 14. In some embodiments, the second portion 14 includes at least a third sub-part and a fourth sub-part spaced apart from each other by the first portion 13. Optionally, the second portion 14 includes a same semiconductor host material doped with a same dopant of a doping concentration in a same range as at least one of the source electrode contact part 11 and the drain electrode contact part 12. Optionally, the source electrode contact part 11, the drain electrode contact part 12, the first portion 13 of the channel part C, and the second portion 14 of the channel part C include a same semiconductor host material.

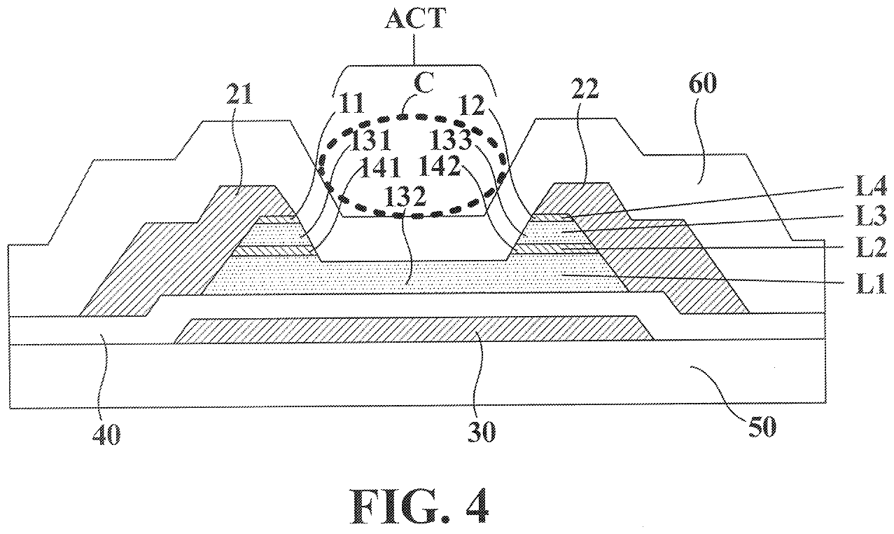

FIG. 4 is a schematic diagram illustrating the structure of a thin film transistor in some embodiments according to the present disclosure. Referring to FIG. 4, the thin film transistor is formed on a base substrate 50. In some embodiments, the thin film transistor includes a gate electrode 30, a gate insulating layer 40 on a side of the gate electrode 30 distal to the base substrate 50, an active layer ACT on a side of the gate insulating layer 40 distal to the gate electrode 30, a source electrode 21 and a drain electrode 22 on a side of the active layer ACT distal to the gate insulating layer 40. and a passivation layer 60 on a side of the source electrode 21 and the chain electrode 22 distal to the base substrate 50. The gate insulating layer 40 insulates the active layer ACT from the gate electrode 30, and provides a. proper spacing, between the active layer ACT and the gate electrode 30. The active layer ACT includes a source electrode contact part 11, a drain electrode contact part 12, and a Channel part C between the source electrode contact part 11 and the drain electrode contact part 12. In some embodiments, and as shown in FIG. 4, the active layer ACT has a multi-layer structure having a first layer L1, a second layer L2 on the first layer L1, a third layer L3 on a side of the second layer L2 distal to the first layer L1, and a fourth layer L4 on a side of the third layer L3 distal to the second layer L1 Optionally, as shown in FIG. 4, the first portion of the channel part C includes a first sub-part 131, a second sub-part 132. and a fifth sub-part 133. The second portion of the channel part C (having an enhanced ability to capture off-state leaking carriers as compared to the first portion) optionally includes a third sub-part 141 and a fourth sub-part 142. Optionally. the second layer L2 constitutes the second portion of the channel part C, i.e., the third sub-part 141 and the fourth sub-part 142 are in the second layer L2. Optionally, the first layer L1 and the third layer L3 constitute the first portion of the channel part C, i.e., the first sub-part 131 is in the first layer L1, and the second sub-part 132 and the fifth sub-part 133 are in the third layer L3. Optionally, the fourth layer L4 constitutes the source electrode contact part 11 and the drain electrode contact part 12, i.e., the source electrode contact part 11 and the drain electrode contact part 12 are in the fourth layer L4.

In some embodiments, and referring to FIG. 4, an orthographic projection of the gate electrode 30 on the base substrate 50 substantially covers an orthographic projection of the active layer ACT. Optionally, the orthographic projection of the gate electrode 30 on the base substrate 50 substantially covers an orthographic projection of the channel part C. The source electrode 21 is connected to the active layer ACT through the source electrode contact part 11, and the drain electrode 22 is connected to the active layer ACT through the drain electrode contact part 12.

In some embodiments, and referring to FIG. 4, the first sub-part 131, the second sub-part 132, and the fifth sub-part 133 are spaced apart from each other by the second portion, and the third sub-part 141 and the fourth sub-part 142 are spaced apart from each other by the first portion. Specifically, the second sub-part 132 is spaced apart from the first sub-part 131 by the third sub-part 141. the fifth sub-part 133 is spaced apart from the first sub-part 131 by the fourth sub-part 142. the third sub-part 141 and the fourth sub-part 142 are spaced apart from each other by the first sub-part 131. Moreover, the source electrode contact part 11 and the third sub-part 141 are spaced apart from each other by the second sub-part 132, and the drain electrode contact part 12 and the fourth sub-part 142 are spaced apart from each other by the fifth sub-part 133.

Various appropriate electrode materials and various appropriate fabricating methods may be used to make the gate electrode 30. the source electrode 21, and the drain electrode 22. For example, an electrode material may be deposited on the substrate by a plasma-enhanced chemical vapor deposition (PECVD)process and patterned. Examples of appropriate electrode materials for making the gate electrode 30, the source electrode 21, and the drain electrode 22, include, but are not limited to, carbon nanotubes, graphene, conductive resins, various metals and alloys such as aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like.

Various appropriate insulating materials and various appropriate fabricating methods may be used to make the gate insulating layer 40, the passivation layer 60, and the base substrate 50. For example, an insulating material may be deposited on the substrate by a plasma-enhanced chemical vapor deposition (PECVD)process and patterned. Examples of appropriate insulating materials for making the gate insulating layer 40, the passivation layer 60, and the base substrate 50 include, but are not limited to, silicon oxide (SiOₓ), silicon nitride (SiN_{y}, e.g., Si₃N₄), silicon oxynitride (SiOₓN_{y}), and insulating resins.

Various appropriate semiconductor materials and various appropriate fabricating methods may be used to make the active layer ACT. For example, a semiconductor material may be deposited on the substrate by a plasma-enhanced chemical vapor deposition (PECVD)process and patterned. Examples of appropriate semiconductor materials for making the active layer ACT includes, but are not limited to, metal oxides (e.g., ITO, IZTO, IGTO), amorphous silicon, polycrystalline silicon, single crystal silicon, organic semiconductor materials, and the like. Optionally, the semiconductor materials may be partially or entirely doped by one or more metal elements, one or more non-metal element, or a combination thereof.

In some embodiments, the second portion 14 includes a doped semiconductor material; and the first portion 13 includes an undoped semiconductor material or a semiconductor material less doped than the second portion 14. In one example, the first portion 13 includes an undoped amorphous silicon material; and each of the source electrode contact part 11, the drain electrode contact part 12, and the second portion 14 of the channel part C includes an N⁺heavily doped amorphous silicon material. Optionally, the first portion 13 includes an undoped hydrogenated amorphous silicon material; and each of the source electrode contact part 11. the drain electrode contact part 12, and the second portion 14 of the channel part C includes an N⁺heavily doped hydrogenated amorphous silicon material. Optionally, the second portion 14 has a doping concentration in a range of approximately 10¹⁷ atom/cm³ to approximately 10²¹ atom cm³.

Referring to FIG. 4, in some embodiments, each of the first sub-part 131, the second sub-part 132, and the fifth sub-part 133 includes an undoped semiconductor material or a semiconductor material less doped than the second portion 14, for example, an undoped amorphous silicon material or an undoped hydrogenated amorphous silicon material. In some embodiments, each of the third sub-part 141 and the fourth sub-part 142 includes a heavily doped semiconductor material, for example, an N⁺heavily doped amorphous silicon material or an N⁺heavily doped hydrogenated amorphous silicon material. Optionally, each of the source electrode contact part 11, the drain electrode contact part 12, the third sub-part 141 and the fourth sub-part 142 includes a heavily doped semiconductor material, for example, an N⁺heavily doped amorphous silicon material or an N⁺heavily doped hydrogenated amorphous silicon material. Various appropriate doping methods may be used for forming the doped amorphous silicon material, e.g., an ion injection doping method and a thermal diffusion doping method. The doping may be performed prior to deposition of the semiconductor material on the base substrate. Optionally, the doping is performed subsequent to deposition of the semiconductor material on the base substrate.

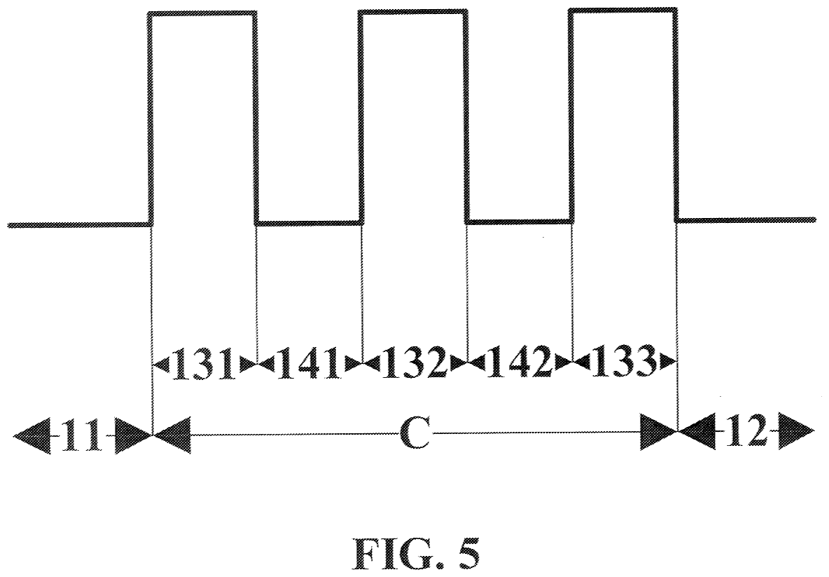

FIG. 5 is a schematic diagram illustrating energy band levels of various portions of a channel part of a thin film transistor in some embodiments according to the present disclosure. Referring to FIG. 5, the source electrode contact part 11, the drain electrode contact part 12, the third sub-part 141 of the channel part C, and the fourth sub-part 142 of the channel part C have relatively lower energy band levels as compared to the energy band levels of the first sub-part 131, the second sub-part 132, and the fifth sub-part 133.

In some embodiments, one or more sub-parts of the second portion 14 completely space apart two sub-parts of the first portion 13 that are directly adjacent to the one or more sub-parts of the second portion 14. In one example, and referring to FIG. 4, the third sub-part 141 of the second portion 14 completely spaced apart the first sub-part 131 and the second sub-part 132 of the first portion 13, and the fourth sub-part 142 of the second portion 14 completely spaced apart the first sub-part 131 and the fifth sub-part 133 of the first portion 13. By having this design, the off-state leaking current can be minimized to a relatively greater degree,

In some embodiments, and referring to FIG. 2, two sub-parts of the first portion 13 that are directly adjacent to, and spaced apart by the second portion 14 or a sub-part thereof remain physically connected with each other, e.g., not completely spaced part by the second portion 14 or a sub-part thereof. By haying this design, the impact of the second portion 14 on the on-state source drain current can be lowered.

The second portion 14 may include one or more sub-parts. In some embodiments, and referring to FIG. 2, the second portion 14 does not include multiple sub-parts, i.e., the second portion 14 includes only one single sub-part.

In some embodiments. and referring to FIG. 4, the second portion 14 includes multiple sub-parts spaced apart by the first portion 13 (e.g., by one or more sub-parts of the first portion 13). By having this design, the total area of the contact interface between the first portion 13 and the second portion 14 can be increased to a relatively greater degree, further reducing the off-state leaking current.

Optionally, the source electrode contact part 11, the drain electrode contact part 12, the first portion 13 of the channel part C. and the second portion 14 of the channel part C constitute a single layer structure in a same layer.

In some embodiments, the first portion 13 and the second portion 14 include different semiconductor host materials. In one example, the first portion 13 includes amorphous silicon as the semiconductor host material, e.g., without doping. In another example, the second portion 14 includes polycrystalline silicon as the semiconductor host material, e.g., doped with a dopant. By having this design, the movements of the off-state carriers can be further restricted, thereby minimizing or eliminating the off-state leaking current. Moreover, the dopant diffusion between the first portion 13 and the second portion 14 can be reduced by having the first portion 13 and the second portion 14 made of different semiconductor host materials.

In some embodiments, the first portion 13 and the second portion 14 include a same semiconductor host material. Optionally, the source electrode contact part 11. the drain electrode contact part 12, the first portion 13, and the second portion 14 include a same semiconductor host material, e.g., an amorphous silicon material, thereby simplifying the fabrication process. In one example, each of the source electrode contact part 11, the drain electrode contact part 12, the first portion 13, and the second portion 14 include an N⁺heavily doped amorphous silicon material.

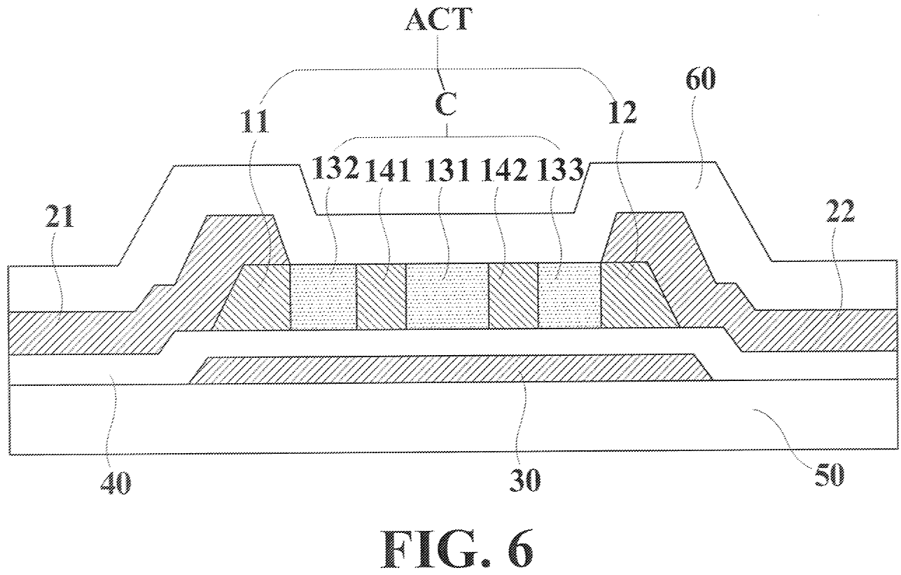

FIG. 6 is a schematic diagram illustrating the structure of ; a thin film transistor in some embodiments according to the present disclosure. Referring to FIG. 6, the source electrode contact part 11, the drain electrode contact part 12, the first portion 13 of the channel part C, and the second portion 14 of the channel part C constitute a single layer structure in a same layer. In some embodiments, the thin film transistor includes a gate electrode 30, a gate insulating layer 40 on a side of the gate electrode 30 distal to the base substrate 50, an active layer ACT on a side of the gate insulating layer 40 distal to the gate electrode 30, a source electrode 21 and a drain electrode 22 on a side of the active layer ACT distal to the gate insulating layer 40, and a passivation layer 60 on a side of the source electrode 21 and the drain electrode 22 distal to the base substrate 50. The gate insulating layer 40 insulates the active layer ACT from the gate electrode 30, and provides a proper spacing between the active layer ACT and the gate electrode 30. The active layer ACT includes a source electrode contact part 11, a drain electrode contact part 12, and a channel part C between the source electrode contact part 11 and the drain electrode contact part 12. In some embodiments, and as shown in FIG. 6. the active layer ACT has a single layer structure. The active layer ACT includes a source electrode contact part 11, a second sub-part 132 of the first portion 13 directly adjacent to the source electrode contact part 11, a third sub-part 141 of the second portion 14 directly adjacent to the second sub-part 132 of the first portion 13, a first sub-part 131 of the first portion 13 directly adjacent to the third sub-part 141 of the second portion 14, a fourth sub-part 142 of the second portion 14 directly adjacent to the first sub-part 131 of the first portion 13, a fifth sub-part 133 of the first portion 13 directly adjacent to the fourth sub-part 142 of the second portion 14, and a drain electrode contact part 12 directly adjacent to the fifth sub-part 133 of the first portion 13. Optionally, the source electrode contact part 11. the second sub-part 132, the third sub-part 141, the first sub-part 131, the fourth sub-part 142, the fifth sub-part 133, and the drain electrode contact part 12 are all in direct contact (e.g., without any intermediate structure or component) with a same insulating layer (e.g., the gate insulating layer 40) underneath the active layer ACT. Optionally, the source electrode contact part 11, the second sub-part 132, the third sub-part 141, the first sub-part 131, the fourth sub-part 142, the fifth sub-part 133, and the drain electrode contact part 12 are substantially on a same horizontal plane.

In some embodiments and referring to FIG. 6, an orthographic projection of the gate electrode 30 on the base substrate 50 substantially covers an orthographic projection of the active layer ACT. Optionally, the orthographic projection of the gate electrode 30 on the base substrate 50 substantially covers an orthographic projection of the channel part C. The source electrode 21 is connected to the active, layer ACT through the source electrode contact part 11, and the drain electrode 22 is connected to the active layer ACT through the drain electrode contact part 12.

FIG. 4 and FIG. 6 illustrate bottom gate thin film transistors. In some embodiments, the thin film transistor is a top gate thin film transistor. Specifically, the top gate thin film transistor includes an active layer on a base substrate, a gate insulating layer on a side of the active layer distal to the base substrate, and a gate electrode on a side of the gate insulating layer distal to the active layer, Optionally, the top gate thin film transistor further includes a source electrode connected to the source electrode contact part of the active layer, and a drain electrode connected to the drain electrode contact part of the active layer. The active layer in the top gate thin film transistor has a structure described herein. For example, the active layer in the top gate thin film transistor includes a source electrode contact part, a drain electrode contact part, and a channel part between the source electrode contact part and the drain electrode contact part. The channel part includes at least a first portion and a second portion different from the first portion. The second portion has an enhanced ability to capture off-state leaking carriers as compared to the first portion.

In another aspect, the present disclosure provides a method of fabricating a thin film transistor. In some embodiments, the method includes forming an active layer. In some embodiments, forming the active layer includes forming a source electrode contact part, forming a drain electrode contact part, and forming a channel part between the source electrode contact part and the drain electrode contact part. Optionally, forming the channel part includes forming at least a first portion and forming a second portion different from the first portion, the second portion formed to capture off-state leaking carriers.

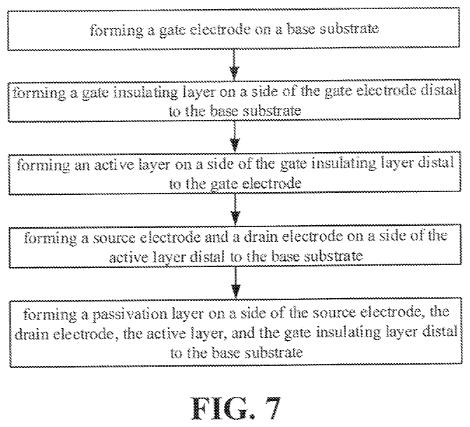

FIG. 7 is a flow chart illustrating a method of fabricating a thin film transistor in some embodiments according to the present disclosure. Referring to FIG. 7, the method in some embodiments includes forming a gate electrode on a base substrate; forming a gate insulating layer on a side of the gate electrode distal to the base substrate; forming an active layer on a side of the gate insulating layer distal to the gate electrode; forming a source electrode and a drain electrode on a side of the active layer distal to the base substrate; and forming a passivation layer on a side of the source electrode, the drain electrode, the active layer, and the gate insulating layer distal to the base substrate. FIG. 7 illustrate a method of fabricating a bottom gate thin film transistor. In some embodiments, the thin film transistor is a top gate thin film transistor. In some embodiments, the method of fabricating the top gate thin film transistor includes forming an active layer on a base substrate, forming a gate insulating layer on a side of the active layer distal to the base substrate, and forming a gate electrode on a side of the gate insulating layer distal to the active layer. Optionally, the method of fabricating the top gate thin film transistor further includes forming a source electrode connected to the source electrode contact part of the active layer, and forming a drain electrode connected to the drain electrode contact part of the active layer.

In some embodiments, the step of forming the gate electrode includes cleaning and drying a surface of the base substrate, depositing a conductive material layer on the base substrate. e.g., by a physical vapor deposition process; patterning the conductive material layer thereby forming the gate electrode. Optionally, patterning the conductive material layer includes forming a photoresist layer on the conductive material layer; exposing and developing the photoresist layer to form a photoresist pattern corresponding to a pattern of the gate electrode; removing a portion of the conductive material layer exposed by the photoresist pattern; and removing the photoresist layer, thereby forming, the gate electrode.

In some embodiments, the step of forming the gate insulating layer includes depositing an insulating material layer on a side of the gate electrode distal to the base substrate, e.g., by a chemical vapor deposition process.

In some embodiments, the active layer is for ted to include a source electrode. contact part, a drain electrode contact part, and a channel part between the source electrode contact part and the drain electrode contact part. Optionally, the channel part is formed to include at least a first portion and a second portion different from the first portion. Optionally, the second portion is formed to have an enhanced ability to capture off-state leaking carriers as compared to the first portion.

In some embodiments, the step of forming the source electrode and the drain electrode includes depositing a conductive material layer on the base substrate, e.g., by a physical vapor deposition process; patterning the conductive material layer thereby forming the source electrode and the drain electrode. Optionally, patterning the conductive material layer includes forming a photoresist layer on the conductive material layer: exposing and developing the photoresist layer to form a photoresist pattern corresponding to a pattern of the source electrode and the drain electrode; removing, a portion of the conductive material layer exposed by the photoresist pattern; and removing the photoresist layer, thereby forming the source electrode and the drain electrode,

In some embodiments, the step of forming the passivation layer, includes depositing an insulating material layer on a side of the source electrode, the drain electrode, the active layer, and the gate insulating layer distal to the base substrate, e.g., by a chemical vapor deposition process.

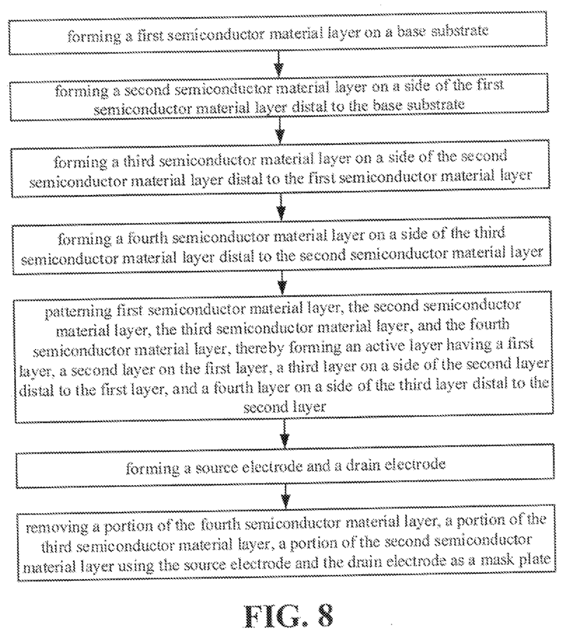

FIG. 8 is a flow chart illustrating a method of fabricating a thin film transistor in some embodiments according to the present disclosure. Referring to FIG. 8. the method in some embodiments includes forming a first semiconductor material layer on a base substrate; forming a second semiconductor material layer on a side of the first semiconductor material layer distal to the base substrate; forming a third semiconductor material layer on a side of the second semiconductor material layer distal to the first semiconductor material layer; forming a fourth semiconductor material layer on a side of the third semiconductor material layer distal to the second semiconductor material layer; and patterning first semiconductor material layer, the second semiconductor material layer, the third semiconductor material layer, and the fourth semiconductor material layer, thereby forming an active layer having a first layer, a second layer on the first layer, a third layer on a side of the second layer distal to the first layer, and a fourth layer on a side of the third layer distal to the second layer. The method further includes forming a source electrode and a drain electrode. Optionally, the step of patterning the first semiconductor material layer, the second semiconductor material layer, the third semiconductor material layer, and the fourth semiconductor material layer includes removing a portion of the fourth semiconductor material layer, a portion of the third semiconductor material layer, a portion of the second semiconductor material layer using the source electrode and the drain electrode as a mask plate.

In some embodiments, forming the first semiconductor material layer includes depositing an undoped (or lightly doped) semiconductor material (e.g., amorphous silicon); forming the second semiconductor material layer includes depositing a doped (e.g., heavily doped) semiconductor material (e.g., amorphous silicon); forming the third semiconductor material layer includes depositing an undoped (or lightly doped) semiconductor material (e.g., amorphous silicon); forming the fourth semiconductor material layer includes depositing a doped (e g., N+heavily doped) semiconductor material (e.g., amorphous silicon).

In some embodiments, forming the second semiconductor material layer includes depositing an undoped semiconductor material (e.g., amorphous silicon); and doping the undoped semiconductor material with a dopant (e.g., an N+dopant). In some embodiments, forming the fourth semiconductor material layer includes depositing an undoped semiconductor material (e.g., amorphous silicon); and doping the undoped semiconductor material with a dopant (e.g., an N+dopant).

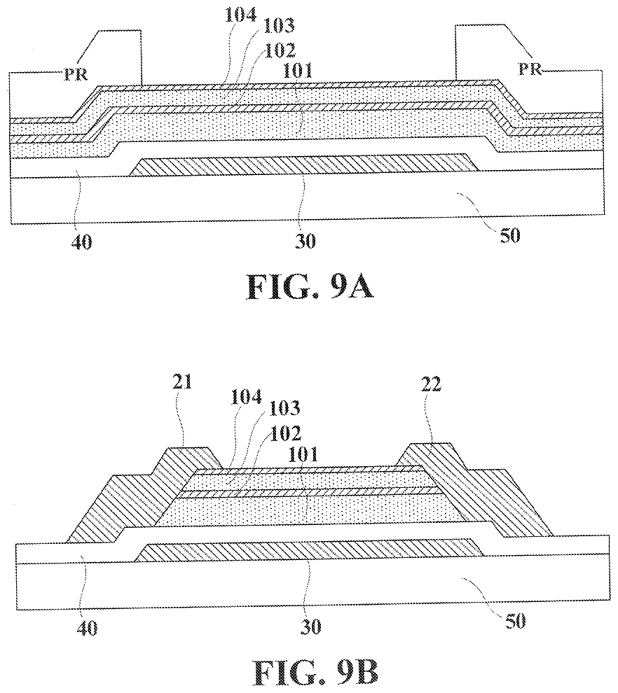

FIGS. 9A to 9C illustrate a process of fabricating a thin film transistor in some embodiments according to the present disclosure. Referring to FIG. 9A, a first semiconductor material layer 101 is formed on a base substrate 50, e.g., on a side of the gate insulating layer 40 distal to the gate electrode. A second semiconductor material layer 102 is formed on a side of the first semiconductor material layer 101 distal to the base substrate 50. A third semiconductor material layer 103 is formed on a side of the second semiconductor material layer 102 distal to the first semiconductor material layer 101. A fourth semiconductor material layer 104 is formed on a side of the third semiconductor material layer 103 distal to the second semiconductor material layer 102.

In some embodiments, the step of patterning the first semiconductor material layer 101, the second semiconductor material layer 102, the third semiconductor material layer 103, and the fourth semiconductor material layer 104 includes removing the semiconductor materials in regions outside a region corresponding to the active layer. Referring to FIG. 9A, a photoresist layer PR is formed on a side of the fourth semiconductor material layer distal to the third semiconductor material layer. The photoresist layer PR is formed to have a photoresist pattern corresponding to the active layer. The first semiconductor material layer 101, the second semiconductor material layer 102, the third semiconductor material layer 103, and the fourth semiconductor material layer 104 are removed outside the photoresist pattern. Subsequently, the photoresist layer PR is removed.

Referring to FIG. 9B, a source electrode 21 and a drain electrode 22 are formed on a side of the first semiconductor material layer 101, the second semiconductor material layer 102. the third semiconductor material layer 103, the fourth semiconductor material layer 104, and the gate insulating layer 40 distal to the base substrate 50. Using the source electrode 21 and the drain electrode 22 as a mask plate, the first semiconductor material layer 101, the second semiconductor material layer 102, the third semiconductor material layer 103, the fourth semiconductor material layer 104 are further patterned.

Referring to FIG. 9C, in a region between the source electrode 21 and the drain electrode 22 and using the source electrode 21 and the drain electrode 22 as the mask plate, a portion of the fourth semiconductor material layer 104, a portion of the third semiconductor material layer 103, and a portion of the second semiconductor material layer 102 are removed. The first semiconductor material layer 101 in the region between the source electrode 21 and the drain electrode 22 remains, thereby forming an active layer having four layers: a first layer L1, a second layer L2 on the first layer L1, a third layer L3 on a side of the second layer L2 distal to the first layer L1, and a fourth layer L4 on a side of the third layer L3 distal to the second layer L2. A first sub-part 131 of the first portion of the channel part C is formed in the first layer L1. A third sub-part 141 and a fourth sub-part 142 of the second portion of the channel part C are fanned in the second layer L2. A second sub-part 132 and a fifth sub-part 133 of the first portion of the channel part C are formed in the third layer L3. A source electrode contact part 11 and a drain electrode contact part 12 are formed in the fourth layer L4. In this step, although the first semiconductor material layer 101 in the region between the source electrode 21 and the drain electrode 22 remains, over-etching may be applied to remove a surface portion of the first semiconductor material layer 101, to ensure no residual semiconductor material from the second semiconductor material layer 102 remains in this region. Optionally, a wet etchant is used for etching the portion of the fourth semiconductor material layer 104, the portion of the third semiconductor material layer 103, and the portion of the second semiconductor material layer 102 in this region. Optionally, the wet etchant is potassium hydroxide.

In this example, the second portion of the channel part can be formed without the need of additional numbers of mask plates. In particular, the source electrode 21 and the. drain electrode 22 may be used as a mask plate for patterning the active layer in regions between the source electrode 21 and the drain electrode 22, greatly simplifying the fabrication process. Moreover, the second portion (e.g., sub-parts of the second portion) may be formed without the need of a doping process subsequent to the deposition, inadvertent damages to the device introduced by an ion injection doping process can be avoided, and dopant diffusion between different regions of the active layer can be reduced.

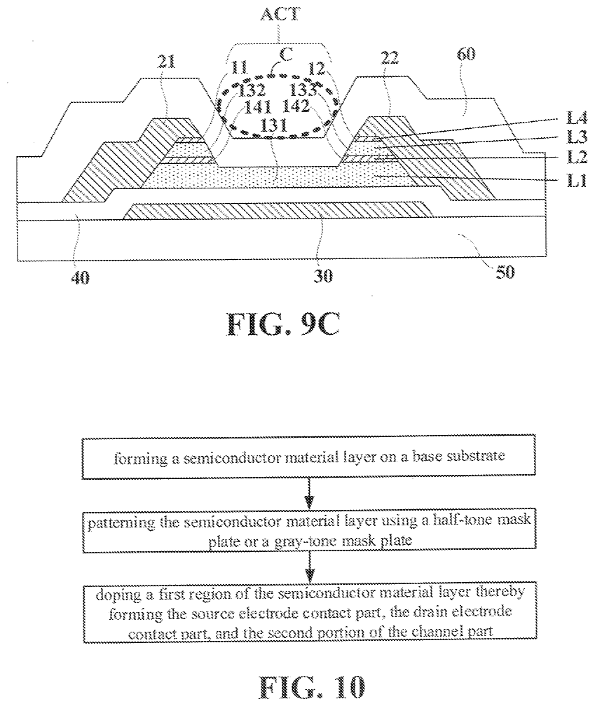

In some embodiments, the active layer is formed to have a single-layer structure in a same layer. FIG. 10 is a flow chart illustrating a method of fabricating a thin film transistor in some embodiments according to the present disclosure. Referring to FIG. 10, the method in some embodiments includes forming a semiconductor material layer on a base substrate; patterning the semiconductor material layer using a half-tone mask plate or a gray-tone mask plate; and doping a first region of the semiconductor material layer thereby forming the source electrode contact part, the drain electrode contact part, and the second portion of the channel part.

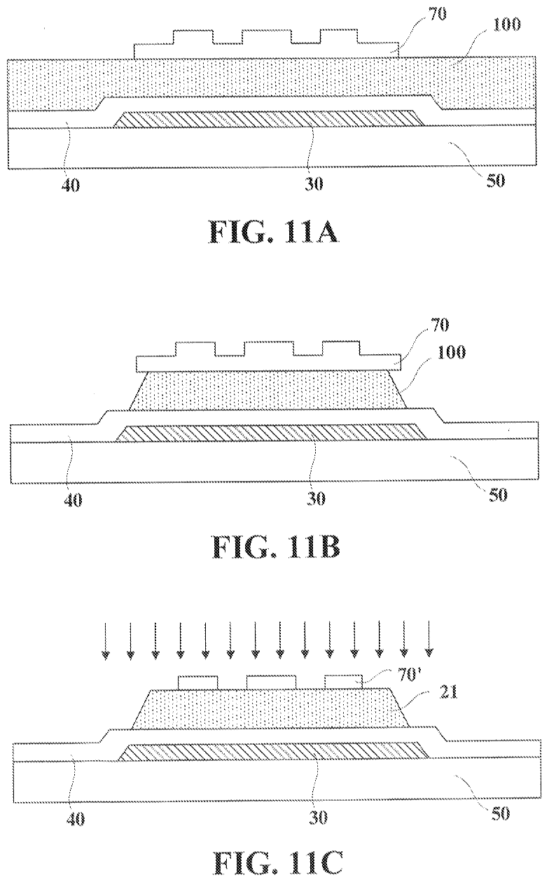

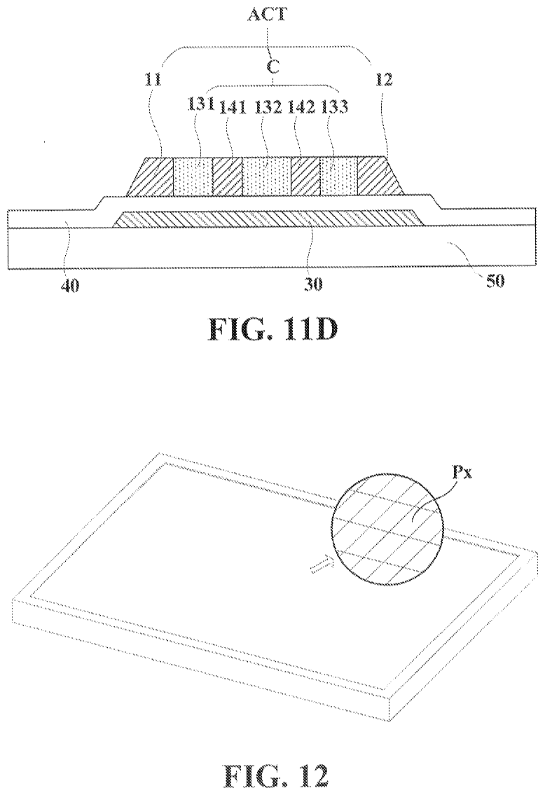

FIGS. 11A to 11D illustrate a process of fabricating a thin film transistor in some embodiments according to the present disclosure. Referring to FIG. 11A, a semiconductor material layer 100 is formed on a base substrate 50, e.g., on a side of the gate insulating layer 40 distal to the gate electrode 30, e.g., by a chemical vapor deposition process. A photoresist layer 70 is formed on the semiconductor material layer 100 using a half-tone mask plate or a gay-tone mask plate. The photoresist layer 70 is formed to have a first thickness in at least a first region and a second thickness in at least a second region, the second thickness greater than the first thickness. The second region having the second thickness corresponds to the first portion of the channel part, and the first region having the first thickness corresponds to the second portion of the channel part, and optionally also corresponds to the source electrode. contact part and the drain electrode contact part.

Referring to FIG. 11B, the semiconductor material of the semiconductor material layer 100 in regions outside the photoresist layer 70 is removed. Semiconductor material of the semiconductor material layer 100 in regions corresponding to the active layer remains.

Referring to FIG. 11C, the photoresist layer 70 is asked to reduce the thickness, thereby forming a second photoresist layer 70′. Specifically, the photoresist layer 70 is completely removed in regions having the first thickness, and a thickness of the photoresist layer 70 in regions having the second thickness is reduced but not completely removed. The semiconductor material in the semiconductor material layer 100 in regions corresponding to the source electrode contact part, the drain electrode contact part, and the second portion is exposed by the second photoresist layer 70′. The semiconductor material layer 100 is then. subject to a doping process. As shown in FIG. 11C, an ion injection doping process is performed to dope the semiconductor material layer 100 in regions corresponding to the source electrode contact part, the drain electrode contact part, aid the second portion. Optionally, the doping is an N+heavy doping.

Referring to FIG. 11D, the second photoresist layer 70′ is removed subsequent to the doping process. An active layer ACT is thereby formed to include a source electrode contact part 11, a second sub-part 132 of the first portion 13 directly adjacent to the source electrode contact part 11, a third, sub-part 141 of the second portion 14 directly adjacent to the second sub-part 132 of the first portion 13, a first sub-part 131 of the first portion 13 directly adjacent to the third sub-part 141 of the second portion 14, a fourth sub-pad, 142 of the second portion 14 directly adjacent to the first sub-part 131 of the first portion 13, a fifth sub-part 133 of the first portion 13 directly adjacent to the fourth sub-part 142 of the second portion 14, and a drain electrode contact part 12 directly adjacent to the fifth sub-part 133 of the first portion 13. Optionally, the source electrode contact part 11, the second sub-part 132, the third sub-part 141, the first sub-part 131, the fourth sub-part 142, the fifth sub-part 133, and the drain electrode contact part 12 are formed to be in direct contact (e.g., without any intermediate structure or component) with a same insulating layer (e.g., the gate insulating layer 40) underneath the active layer ACT. Optionally, the source electrode contact part 11, the second sub-part 132, the third sub-part 141, the first sub-part 131. the fourth sub-part 142. the fifth sub-part 133, and the drain electrode contact part 12 are formed to be substantially on a same horizontal plane.

In this example, the second portion of the channel part can be formed without the need of additional numbers of mask plates. In particular, a half-tone mask plate or a gray-tone mask plate is used for patterning the active layer. In combination with the doping process (e.g., the ion injection doping process), the fabrication process is greatly simplified and manufacturing costs lowered.

In another aspect, the present disclosure provides a display substrate having a thin film transistor described herein or fabricated by a method described herein. Optionally, the display substrate is an array substrate. Optionally, the display substrate is a counter substrate such as a color filter substrate. Optionally, the display substrate is a liquid crystal display substrate. Optionally, the display substrate is an organic light emitting diode display substrate. Optionally, the display substrate is an electrophoretic display substrate. Optionally, the display substrate is a touch control substrate. Because the novel thin film transistor according to the present disclosure having a reduced or eliminated off-state leaking current, the display substrate can be configured to display a static image using a lower frame frequency, thereby achieving a lower power consumption. Moreover, display defects such as crosstalk, residual image, flicker associated with off-state leaking current can be significantly improved.

In another aspect, the present disclosure provides a display panel having a display substrate described herein, or having a thin film transistor described herein or fabricated by a. method described herein.

In another aspect, the present disclosure provides a display apparatus having a display panel described herein, or having a thin film transistor described herein or fabricated by a method described herein. Optionally, the display apparatus is a liquid crystal display apparatus. Optionally=, the display apparatus is an organic light emitting diode display apparatus. Optionally=, the display apparatus is an electrophoretic display apparatus. Examples of appropriate display apparatuses include, but are not limited to, an electronic paper, a mobile phone, a tablet computer, a television, a monitor, a notebook computer, a digital album, a GPS, etc. FIG. 12 is a schematic diagram illustrating the structure of a display apparatus in some embodiments according to the present disclosure. Referring to FIG. 12, the display apparatus in some embodiments includes a plurality of subpixels Px arranged in an array having a plurality of rows and a plurality of columns. Optionally, each of the plurality of subpixels Px includes at least one thin film transistor described herein or fabricated by a method described herein. Because the novel thin film transistor according to the present disclosure having a reduced or eliminated off-state leaking current, the display apparatus can be configured to display a static image using a lower frame frequency, thereby achieving a lower power consumption. Moreover, display defects such as crosstalk, residual image, flicker associated with off-state leaking current can be significantly=improved,

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated, It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation an the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. A thin film transistor, comprising an active layer;
wherein the active layer comprises a source electrode contact part, a drain electrode contact part, and a channel part between the source electrode contact part and the drain electrode contact part;
wherein the channel part comprises at least a first portion and a second portion different from the first portion, the second portion having an enhanced ability to capture off-state leaking carriers as compared to the first portion.

2. The thin film transistor of claim 1, wherein off-state energy band levels of a material of the second portion are lower than off-state energy band levels of a material of the first portion.

3. The thin film transistor of claim 2, wherein off-state energy band levels of materials of the second portion, the source electrode contact part, and the drain electrode contact part are lower than the off-state energy band levels of the material of the first portion.

4. The thin film transistor of claim 1, wherein the first portion comprises at least a first sub-part and a second sub-part spaced apart from each other by the second portion.

5. The thin film transistor of claim 1, wherein the second portion comprises at least a third sub-part and a fourth sub-part spaced apart from each other by the first portion.

6. The thin film transistor of claim 1, wherein the second portion comprises a same semiconductor host material doped with a same dopant of a doping concentration in a same range as at least one of the source electrode contact part and the drain electrode contact part.

7. The thin film transistor of claim 1, wherein the source electrode contact part, the drain electrode contact part, the first portion of the channel part, and the second portion of the channel part comprises a same semiconductor host material.

8. The thin film transistor of claim 1, wherein the source electrode contact part, the drain electrode contact part, the first portion of the channel part, and the second portion of the channel part constitute a single layer structure in a same layer.

9. The thin film transistor of claim 1, wherein the active layer has a multi-layer structure comprising a first layer, a second layer on the first layer, a third layer on a side of the second layer distal to the first layer, and a fourth layer on a side of the third layer distal to the second layer;
the second layer constitutes the second portion of the channel part;
the first layer and the third layer constitute the first portion of the channel part; and
the fourth layer constitutes the source electrode contact part and the drain electrode contact part.

10. The thin film transistor of claim 9, wherein the first portion comprises at least a first sub-part, a second sub-part, and a fifth subpart spaced apart from each other by the second portion, the first sub-part being in the first layer, the second sub-part and the fifth sub-part being in the third layer;
the second portion comprises at least a third sub-part and a fourth sub-part spaced apart from each other by the first portion, the third sub-part and the fourth sub-part being in the second layer;
the second sub-part is spaced apart from the first sub-part by the third sub-part;
the fifth sub-part is spaced apart from the first sub-part by the fourth sub-part;
the third sub-part and the fourth sub-part are spaced apart from each other by the first sub-part;
the source electrode contact part and the third sub-part are spaced apart from each other by the second sub-part; and
the drain electrode contact part and the fourth sub-part are spaced apart from each other by the fifth sub-part.

11. The thin film transistor of claim 1, wherein the second portion comprises a doped semiconductor material; and
the first portion comprises an undoped semiconductor material or a semiconductor material less doped than the second portion.

12. The thin film transistor of claim 11, wherein the first portion comprises an undoped amorphous silicon material; and
each of the source electrode contact part, the drain electrode contact part, and the second portion of the channel part comprises an N⁺heavily doped amorphous silicon material.

13. The thin film transistor of claim 11, wherein the second portion has a doping concentration in a range of approximately 10¹⁷ atom/cm³ to approximately 10²¹ atom/cm³.

14. A display substrate, comprising the thin film transistor of claim 1.

15. A display panel, comprising the display substrate of claim 14.

16. A method of fabricating a thin film transistor, comprising forming an active layer;
wherein forming the active layer comprises forming a source electrode contact part, forming a drain electrode contact part, and forming a channel part between the source electrode contact part and the drain electrode contact part;
wherein forming the channel part comprises forming at least a first portion and forming a second portion different from the first portion, the second portion formed to capture off-state leaking carriers.

17. The method of claim 16, wherein forming the active layer comprises:
forming a semiconductor material layer on a base substrate;
patterning the semiconductor material layer using a half-tone mask plate or a gray-tone mask plate; and
doping a first region of the semiconductor material layer thereby forming the source electrode contact part, the drain electrode contact part, and the second portion of the channel part.

18. The method of claim 16, wherein forming the active layer comprises:
forming a first semiconductor material layer on a base substrate;
forming a second semiconductor material layer on a side of the first semiconductor material layer distal to the base substrate;
forming a third semiconductor material layer on a side of the second semiconductor material layer distal to the first semiconductor material layer;
forming a fourth semiconductor material layer on a side of the third semiconductor material layer distal to the second semiconductor material layer;
patterning first semiconductor material layer, the second semiconductor material layer, the third semiconductor material layer, and the fourth semiconductor material layer, thereby forming an active layer having a first layer, a second layer on the first layer, a third layer on a side of the second layer distal to the first layer, and a fourth layer on a side of the third layer distal to the second layer;
wherein a first sub-part of the first portion of the channel part in the first layer;
a third sub-part and a fourth sub-part of the second portion of the channel part in the second layer;
a second sub-part and a fifth sub-part of the first portion of the channel part in the third layer; and
a source electrode contact part and a drain electrode contact part in the fourth layer.

19. The method of claim 18, wherein forming the second semiconductor material layer comprises depositing a semiconductor host material layer and doping the semiconductor host material layer; and
forming the fourth semiconductor material layer comprises depositing a semiconductor host material layer and doping the semiconductor host material layer.

20. The method of claim 18, further comprises forming a source electrode and a drain electrode;
wherein patterning the first semiconductor material layer, the second semiconductor material layer, the third semiconductor material layer, and the fourth semiconductor material layer comprises removing a portion of the fourth semiconductor material layer, a portion of the third semiconductor material layer, a portion of the second semiconductor material layer using the source electrode and the drain electrode as a mask plate.
